(19) United States
(12) Patent Application Publication
(10) Pub. No.: US 2011/0001582 A1
(43) Pub. Date: Jan. 6, 2011

(54) MICRO-ELECTROMECHANICAL DEVICE AND METHOD FOR FABRICATING THE SAME

(75) Inventor: Hironori Nagasaki, Osaka (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Sanyo Electric Co., Ltd., Moriguchi-shi, Osaka (JP)

(21) Appl. No.: 12/918,222

(22) PCT Filed: Feb. 9, 2009
(86) PCT No.: PCT/JP2009/052145

§ 371 Date: Aug. 18, 2010

(30) Foreign Application Priority Data
Feb. 18, 2008 (JP) 2008-035718

(51) Int. Cl. H03H 9/24; H05K 13/00

(52) U.S. Cl. 333/200; 29/592.1

(57) ABSTRACT

A micro-electromechanical device of the present invention includes a resonator and an electrode facing each other, a pair of thermal oxide film formed on the surfaces of the resonator and electrode facing each other and a narrow gap provided between the thermal oxide films. A process for fabricating a micro-electromechanical device includes a step of processing an Si layer to be the resonator and the electrode by using photolithography and etching to form a groove to be a gap, and a step of performing thermal oxidation on the Si layer to form a pair of thermal oxide films of Si on the opposite surfaces of the groove.

### TECHNICAL FIELD

The present invention relates to a structure and a manufacturing method of a micro-electromechanical device such as a micromechanical resonator, micromechanical capacitor or the like which is produced using fine processing technology in the field of semiconductor.

### BACKGROUND ART

In recent years, there has been developed a so-called micro-electromechanical system (MEMS) technology for forming a fine mechanical structure integrated with an electronic circuit, using fine processing technology in the field of semiconductor. Considered is the application of the technology to a filter and a resonator.

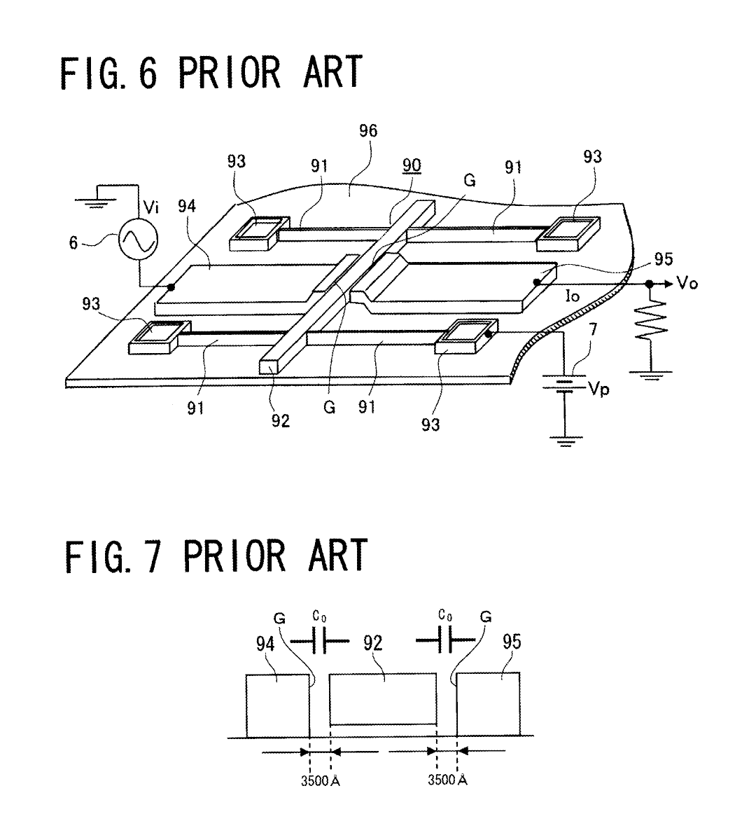

FIG. 6 shows a conventional micromechanical resonator using the MEMS technology (Non-patent Literature 1). The micromechanical resonator includes a resonator 90 on a substrate 96 as shown in the Figure, and the resonator 90 comprises a prismatic resonance beam 92 and four prismatic support beams 91-91 for supporting both end parts of the resonance beam 92. A base end part of each support beam 91 is fixed on the substrate 96 by an anchor 93. The resonator 90 is thereby held at a position that is slightly levitated above a surface of the substrate 96.

Also, an input electrode 94 and an output electrode 95 are arranged across a central part of the resonance beam 92 on both sides of the resonance beam 92 of the resonator 90, defining predetermined gaps G between the resonance beam 92 and both the electrodes 94, 95.

A high frequency power source 6 is connected to the input electrode 94, and a principal voltage power source 7 is connected to one anchor 93.

When a high frequency signal Vi is input into the input electrode 94 while applying a DC voltage Vp to the resonator 90 through the anchor 93, an alternating electrostatic force is generated between the input electrode 94 and the resonance beam 92 through one of the gaps G, and the resonator 90 vibrates due to the electrostatic force in a plane parallel to the surface of the substrate 96. The vibration of the resonator 90 changes the capacitances to be formed between the resonance beam 92 and both the electrodes 95, 94, and the change of the capacitances is output as a high frequency signal Io from the output electrode 95.

In the micromechanical resonator described above, capacitances Co formed between the resonance beam 92 and both the electrodes 94, 95 are determined by the size of the gaps G as shown in FIG. 7, and the smaller the gaps G are, the greater the capacitances Co grow. It is desirable for the gaps G to be small in view of characteristics such as insertion loss or impedance.

Therefore, in the manufacturing process of the micromechanical resonator described above, groove processing using photolithography and etching is used to form the gaps G between the resonance beam 92 and the right and left electrodes 94, 95.

Non-patent Literature 1: W. -T. Hsu, J. R. Clark, and C. T. -C. Nguyen, “Q-optimized lateral free-free beam micromechanical resonators,” Digest of Technical papers, the 11th Int. Conf. on Solid-State Sensors & Actuators (Transducers'01), Munich, Germany, Jun. 10-14, 2001, pp. 1110-1113.

Patent Literature 1: Japanese Unexamined Patent Application Publication No. 2002-535865

### DISCLOSURE OF THE INVENTION

1. Problems To Be Solved By the Invention

In order to set the resonance frequency of the micromechanical resonator in a range from several hundreds of MHz bands to GHz bands, it is necessary to form the gaps G between the resonance beam 92 and the electrodes 94, 95 in submicron order (0.1-0.5 μm).

However, in the conventional groove processing using photolithography and etching, when an i-line exposure device is used, for example, the limit of a groove width which can be formed is around 0.35 μm, and it is difficult to form a groove having a width narrower than that.

Therefore, the present invention is to provide a structure and a manufacturing method of the micro-electromechanical device in which the gaps can be made narrower.

2. Means For Solving the Problem

A micro-electromechanical device according to the present invention comprises two members facing each other and a capacitance according to a gap between the members, the device operates based on the capacitance, and a pair of thermal oxide films is formed on facing surfaces of the two members to define a narrowed gap between the thermal oxide films.

Specifically, one of the pair of members is an electrode and the other is a resonator, and an alternating electrostatic force is generated between the electrode and the resonator by inputting a high frequency signal to provide vibration to the resonator, and a change in capacitance between the electrode and the resonator is output as a high frequency signal.

In order to form a narrowed gap between the two members, a manufacturing method of the micro-electromechanical device of the present invention comprises:

a first gap forming step of processing an Si layer that is to be the two members using photolithography and etching to form a groove that is to be the gap; and a second gap forming step of performing a thermal oxidation treatment on the Si layer provided with the groove to form a pair of Si thermal oxide films on facing surfaces of the groove to define a narrowed gap between the Si thermal oxide films.

In the first gap forming step, by photolithography and etching using an i-line exposure device for example, a groove of around 0.35 μm is formed in the Si layer that is a material of the two members.

Thereafter, by performing a thermal oxidation treatment on the Si layer provided with the groove, the Si thermal oxide films are formed on both side surfaces of the groove, and these Si thermal oxide films are facing each other to define a gap narrowed further from 0.35 μm (e.g., 0.05-0.30 μm).

By performing the thermal oxidation treatment, the Si thermal oxide films having a thickness of at least 0.01 μm or more can be formed.

### EFFECT OF THE INVENTION

With the micro-electromechanical device of the present invention and a method for manufacturing the same, the gap can be further narrowed than in conventional devices and methods.

### BEST MODE FOR CARRYING OUT THE INVENTION

An embodiment of the present invention implemented in an MEMS resonator shown in FIG. 6 is to be described in detail below with reference to the drawings.

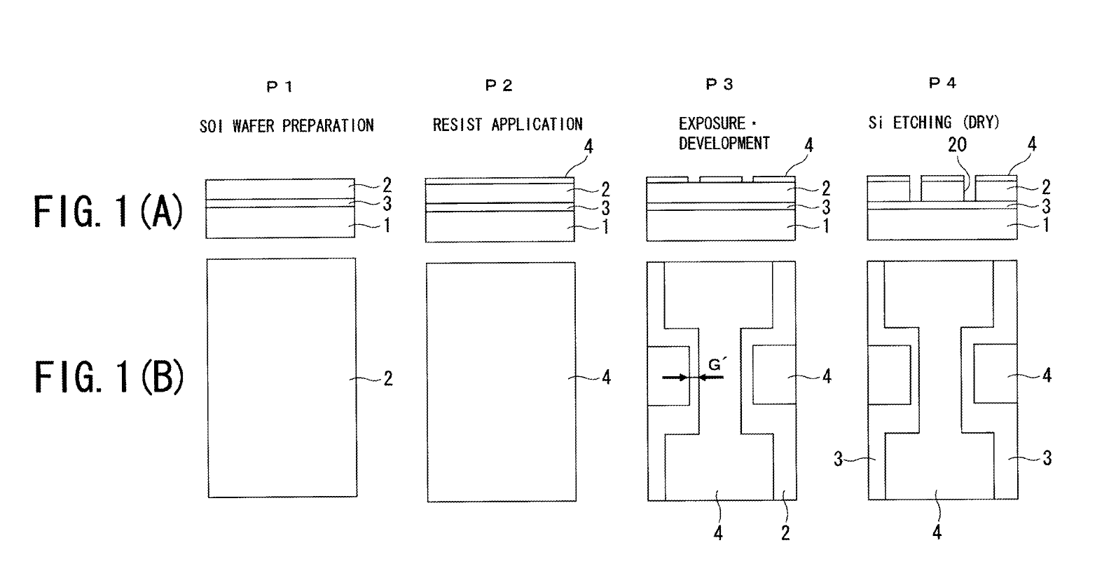

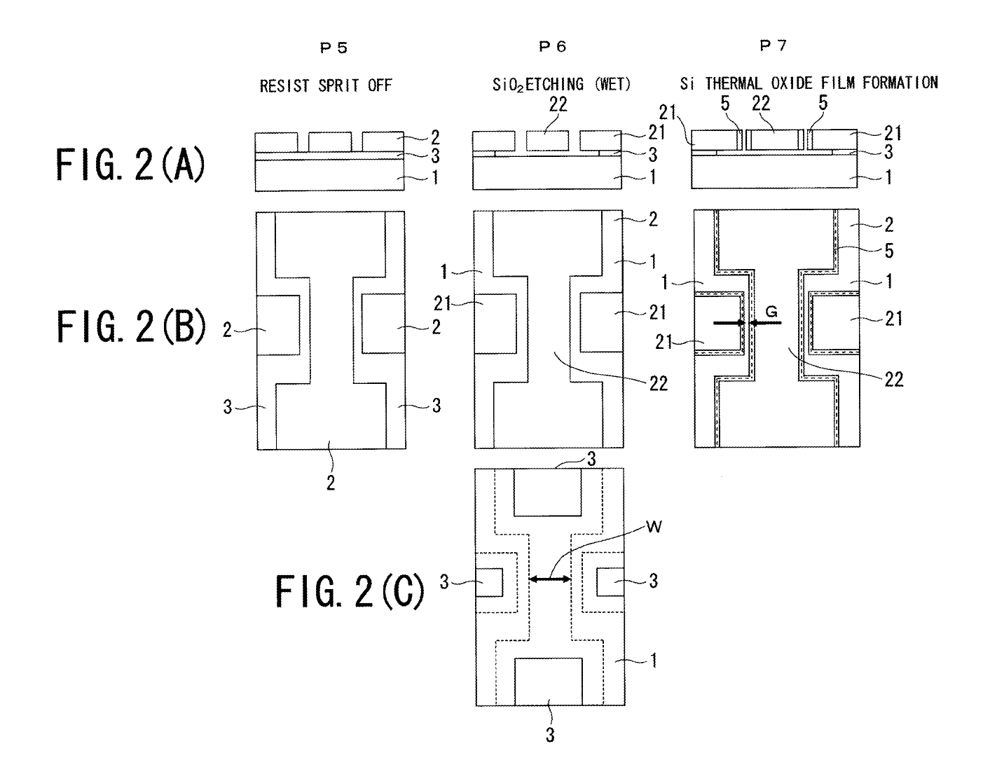

FIGS. 1 and 2 show steps P1-P7 of forming a resonator and right and left electrodes of the MEMS resonator in accordance with the present invention. In FIGS. 1 and 2, (A) is a longitudinal sectional view, and (B) and (C) are plan views.

First, in step P1 of FIG. 1, prepared is an SOI wafer comprising an SiO₂ layer 3 and an Si layer 2 stacked on a surface of an Si layer 1 which is to be a substrate.

Subsequently in step P2, a resist 4 is applied on a surface of the Si layer 2. Then in step P3, exposure using the i-line exposure device and development are conducted on the resist 4 to form a groove pattern having a gap G′. The size limit of the gap G′ is 0.35 μm.

Subsequently in step P4, dry etching is performed on the Si layer 2, so that a groove 20 is formed in the Si layer 2.

In step P5 of FIG. 2, the resist 4 is stripped off, and then in step P6, wet etching is performed on the SiO₂ layer 3 to thereby form a resonator 22 having a width W and right and left electrodes 21, 21. FIG. 2(C) shows surfaces of the SiO₂ layer 3 and the Si layer 1 below, without showing the Si layer 2 located above them.

Thereafter, in step P7, the thermal oxidation treatment at a temperature of 900-1200 degrees Celsius is performed in a mixed gas atmosphere of hydrogen gas and oxygen gas. In this thermal oxidation treatment, hydrogen burns and Si is oxidized in a water-vapor atmosphere.

As a result, a pair of Si thermal oxide films 5, 5 is formed on facing surfaces of the resonator 22 and both the electrodes 21, 21, and a gap G is formed between the Si thermal oxide films 5, 5.

Here, SiO₂ which is an oxide of Si is a stable material, and can form a thin film with high accuracy in a narrow clearance by performing the thermal oxidation treatment. Therefore, the gap G provided by forming the Si thermal oxide films 5, 5 can be narrowed while maintaining high accuracy.

Although the Si thermal oxide films are formed on the whole Si surface which is exposed, only a gap surface is shown in the Figure for description simplification.

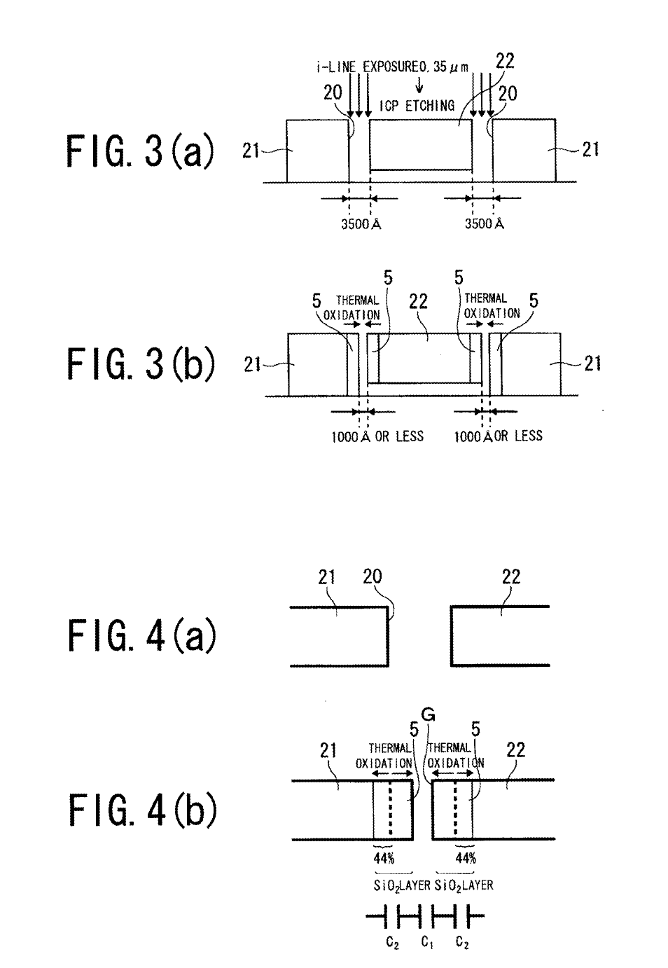

As described above, in the groove processing by i-line exposure and dry etching, the limit of width of the groove 20 to be formed is 0.35 μm as shown in FIG. 3(a). However, by performing a subsequent thermal oxidation treatment, the pair of Si thermal oxide films 5, 5 facing each other is formed between the resonator 22 and both the electrodes 21, 21 as shown in FIG. 3(b), and the gap between the Si thermal oxide films 5, 5 can be narrowed to, for example, 0.1 μm or less.

As shown in FIGS. 4(a) and 4(b), in the process of forming the Si thermal oxide films 5 on both side surfaces of the groove 20 between one of the electrodes 21 and the resonator 22, the Si thermal oxide films 5 grows inward and outward from a side surface of the groove 20 in a ratio of 44% and 56%, and the gap G is defined between the facing surfaces of the pair of Si thermal oxide films 5, 5 facing each other.

As shown in FIG. 4(b), a capacitance C between one of the electrodes 21 and the resonator 22 is a series connection of a capacitance Cl of a vacuum gap formed by the pair of Si thermal oxide films 5, 5 facing each other and two capacitances C₂, C₂ formed by both the Si thermal oxide films 5, 5. Therefore, the following numerical formula is satisfied.

1/C=1/C₂+1/C₁+1/C₂ (Numerical Formula 1)

In the conventional MEMS resonator, a capacitance C₀ of only the vacuum gap is formed as shown in FIG. 7, and the capacitance C ₀ can be represented by the following numerical formula, wherein vacuum permittivity is ε₀, opposing area is S, and the gap is d₀.

C₀=ε₀(S/d₀) (Numerical Formula 2)

Therefore, the capacitance C in the MEMS resonator of the present invention shown in FIG. 4 can be represented by the following numerical formula, with the capacitance C₀ in the conventional MEMS resonator when the gap d₀ is 0.35 μm and a gap d₁ after the thermal oxidation.

C=(931000/(141d₁+437500))·C₀ (Numerical Formula 3)

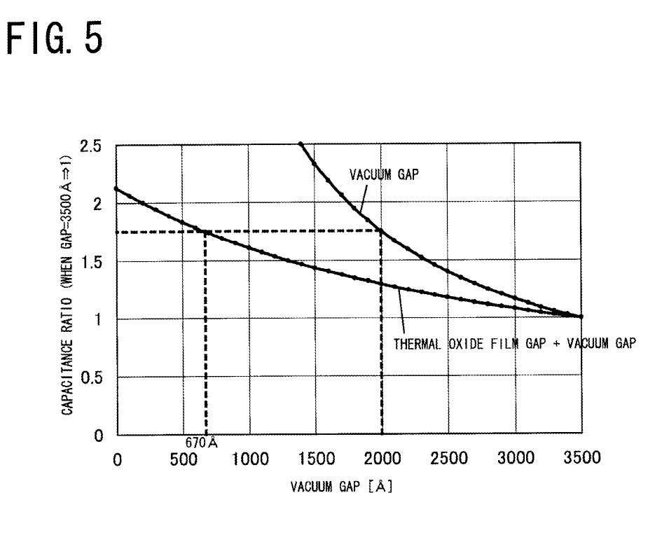

FIG. 5 shows the change in capacitance ratio of the capacitance Co of only the vacuum gap and the capacitance C of combination of a gap of the thermal oxide films and the vacuum gap with the capacitance when the vacuum gap is 0.35 μm as standard.

As indicated by dashed lines in FIG. 5, by forming the vacuum gap of 0.35 μm and thereafter forming the thermal oxide films to such an extent that the gap is narrowed to 0.067 μm, obtained is a capacitance equivalent to an MEMS resonator having only the vacuum gap of 0.2 μm.

Thus, with the MEMS resonator of the present invention, a substantial gap can be further narrowed by forming the Si thermal oxide films 5 than in the conventional resonator, and as a result, characteristics such as insertion loss or impedance can be improved.

The present invention is not limited to the foregoing embodiment in construction but can be modified variously within the technical scope as set forth in the appended claims.

Also, the present invention can be implemented in various micro-electromechanical devices such as an MEMS capacitor, as well as the MEMS resonator.

### BRIEF DESCRIPTION OF THE DRAWINGS

[FIG. 1] FIG. 1 is a series of drawings showing a first half of a manufacturing process of an MEMS resonator in accordance with the present invention;

[FIG. 2] FIG. 2 is a series of drawings showing a latter half of the manufacturing process of the MEMS resonator in accordance with the present invention;

[FIG. 3] FIG. 3 is a cross sectional view showing an etching step and a thermal oxidation step;

[FIG. 4] FIG. 4 is a cross sectional view for explaining a formation of a gap by thermal oxide films;

[FIG. 5] FIG. 5 is a graph showing relation between gap and capacitance in a conventional MEMS resonator having only a vacuum gap and the MEMS resonator of the present invention having both the gap formed by the thermal oxide films and a vacuum gap;

[FIG. 6] FIG. 6 is a perspective view showing a structure of the conventional MEMS resonator; and

[FIG. 7] FIG. 7 is a cross sectional view showing formation of the capacitance of the vacuum gap in the conventional MEMS resonator.

### EXPLANATION OF REFERENCE NUMERALS

1 Si layer

2 Si layer

3 SiO₂ layer

4 resist

5 Si thermal oxide film

20 groove

21 electrode

22 resonator

What is claimed is:

1. A micro-electromechanical device comprising two members facing each other and a capacitance according to a gap between the members, the device operating based on the capacitance, wherein a pair of thermal oxide films is formed on facing surfaces of the two members to define a narrowed gap between the thermal oxide films.

2. The micro-electromechanical device according to claim 1, wherein one of the pair of members is an electrode and the other is a resonator, an alternating electrostatic force is generated between the electrode and the resonator by inputting a high frequency signal to provide vibration to the resonator, and a change in capacitance between the electrode and the resonator is output as a high frequency signal.

3. A method for manufacturing a micro-electromechanical device comprising two members facing each other and a capacitance according to a gap between the members, the device operating based on the capacitance,
wherein the method comprises:
a first gap forming step of processing an Si layer that is to be the two members using photolithography and etching to form a groove that is to be the gap; and
a second gap forming step of performing a thermal oxidation treatment on the Si layer provided with the groove to form a pair of Si thermal oxide films on facing surfaces of the groove to define a narrowed gap between the Si thermal oxide films.

4. The method for manufacturing a micro-electromechanical device according to claim 3, wherein in the first gap forming step, the groove is formed to form an electrode and a resonator made of the Si layer, and in the second gap forming step, the narrowed gap is defined between facing surfaces of one of the Si thermal oxide films on the electrode side and the other of the Si thermal oxide films on the resonator side.
